(19) United States
(12) Patent Application Publication
(10) Pub. No.: US 2008/0067668 A1
(43) Pub. Date: Mar. 20, 2008

(54) Microelectronic package, method of manufacturing same, and system containing same

(76) Inventors: Wei Shi, San Jose, CA (US); Daoqiang Lu, Chandler, AZ (US); Qing Zhou, Chandler, AZ (US); Jiangoi He, Gilbert, AZ (US)

Correspondence Address: INTEL CORPORATION;c/o INTELLEVATE, LLC, P.O. BOX 52050, MINNEAPOLIS, MN, 55402, US

(21) Appl. No.: 11/521,729

(22) Filed: Sep. 15, 2006

(51) Int. Cl. H01L 23/34

(52) U.S. Cl. 257/706

(57) ABSTRACT

A microelectronic package includes a substrate (110), a die (120) electrically connected to the substrate, and a heat dissipation device (130) coupled to the die. The heat dissipation device includes a capacitor (250, 310). In one embodiment the heat dissipation device is a microchannel having a base (131) and a cover plate (132, 300) over the base, and the capacitor is located within the cover plate.

### FIELD OF THE INVENTION

The disclosed embodiments of the invention relate generally to microelectronic packages, and relate more particularly to thermal management and power delivery decoupling solutions in such packages.

### BACKGROUND OF THE INVENTION

The continuing performance increases achieved by computer chips are driven in part by increasingly higher frequency circuit operation. Such high frequency operation leads in turn to increasing amounts of high frequency noise that must be attenuated or removed from the circuit before desired and expected circuit performance levels may be achieved. Power delivery decoupling solutions such as die side capacitors and land side capacitors have been used to filter out circuit noise, but as frequency levels increase the number of decoupling capacitors required to produce the needed capacitance has approached an unmanageable level. The expense associated with using package surface area for increasingly larger numbers of capacitors, as well as the attendant increase in physical dimensions at a time when the trend is toward smaller form factors, further discourage the use of die side and land side capacitors. Another drawback associated with increasing the number of die side and/or land side capacitors is that the additional die side or land side capacitors must be placed at increasingly large distances from the computer chip, the closer locations being occupied by other capacitors or other devices, and this increased distance leads to an increase in inductance in the circuit. Accordingly, there exists a need for a decoupling capacitance solution that is compatible with small form factors, that does not require an unacceptable amount of package real estate, that may be placed close to the device requiring the decoupled signal, and that is capable of adequately addressing the problem of high frequency noise in circuits.

### BRIEF DESCRIPTION OF THE DRAWINGS

The disclosed embodiments will be better understood from a reading of the following detailed description, taken in conjunction with the accompanying figures in the drawings in which:

FIG. 1 is a perspective view of a microelectronic package according to an embodiment of the invention;

FIG. 2 is a cross section of the microelectronic package of FIG. 1 taken along line 2-2 of FIG. 1;

FIG. 3 is a cross sectional view of a microchannel cover plate having an integrated capacitor according to an embodiment of the invention;

FIG. 4 is a flowchart illustrating a method of manufacturing a microelectronic package according to an embodiment of the invention; and

FIG. 5 is a schematic view of a system including a microelectronic package according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner.

### DETAILED DESCRIPTION OF THE DRAWINGS

In one embodiment of the invention, a microelectronic package comprises a substrate, a die electrically connected to the substrate, and a heat dissipation device coupled to the die. The heat dissipation device comprises a capacitor. In one embodiment the heat dissipation device is a microchannel comprising a base and a cover plate over the base, and the capacitor is located within the cover plate. Such placement allows a much larger capacitor, and therefore a greater capacitance, without using any additional real estate on the die. The greater capacitance is desirable because of its usefulness in attenuating greater amounts of high frequency noise.

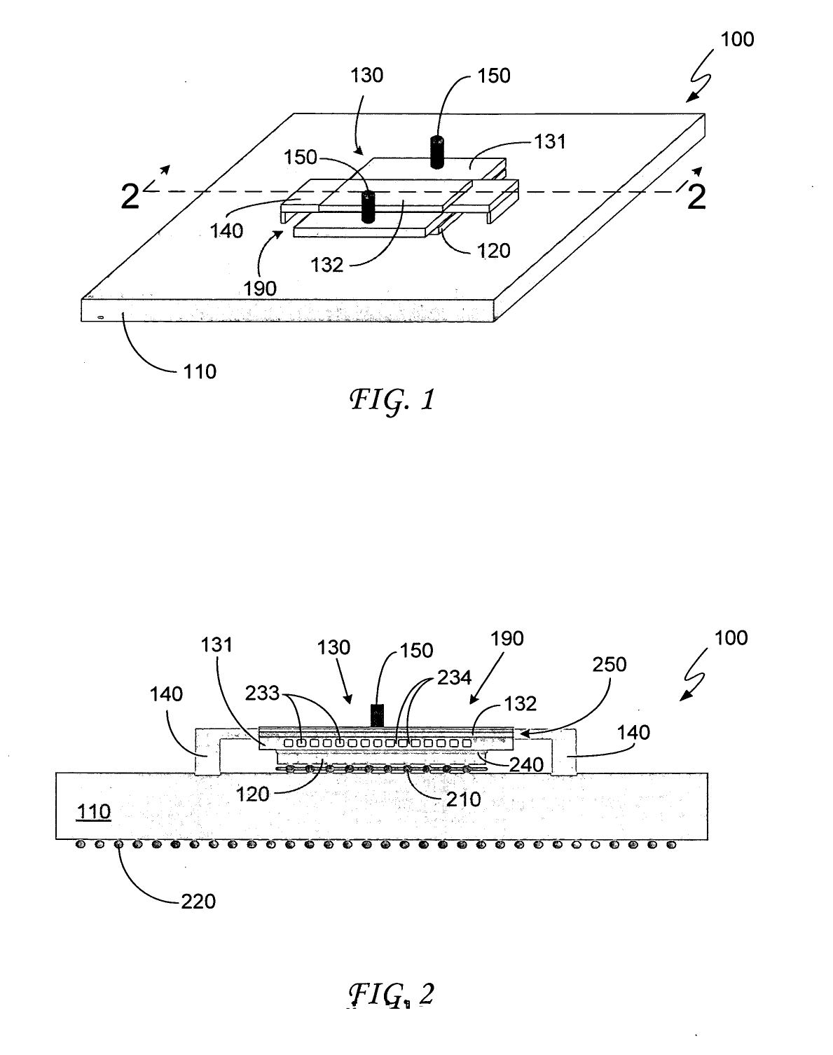

Referring now to the figures, FIG. 1 is a perspective view of a microelectronic package 100 according to an embodiment of the invention and FIG. 2 is a cross section of microelectronic package 100 taken at line 2-2 of FIG. 1. As illustrated in FIGS. 1 and 2, microelectronic package 100 comprises a substrate 110, a die 120 electrically connected to substrate 110, and a heat dissipation device 130 coupled to die 120. As further discussed below, heat dissipation device 130 comprises a capacitor which, although not explicitly shown in FIG. 1, is capable of generating a relatively high capacitance compared to existing land side and die side capacitors while consuming less package surface area.

The need for a decoupling capacitor capable of removing high frequency noise from high-performance computer chips was discussed above. Another requirement of high-performance chips is an effective heat removal system, and this requirement may be met by the use of what is known as a microchannel cold plate, or simply a microchannel, as it will be referred to herein. A typical microchannel comprises a base in which are formed a plurality of channels—sometimes called microchannels because of their relatively small size—separated by fins of material, often a highly thermally conductive material such as copper. These fins collect heat from a die or other device to which they are connected, often with the help of a thermal interface material that is located between and is in direct contact with the die and the microchannel. A cover plate overlies the microchannels and creates an enclosure into which a coolant may be introduced. In one embodiment, coolant at a first temperature is introduced into the base where it flows through the microchannels and contacts the fins. During the coolant's contact with the fins the heat collected by the fins is transferred to the coolant, thus increasing the temperature of the coolant and reducing the temperature of the fins. The heated coolant then flows out of the microchannel base and is eventually cooled, perhaps by a fan or similar cooling mechanism, at which point it is ready to repeat the cycle. Microchannels are a relatively new development in thermal management, but have already shown promise as a potential thermal dissipation solution.

In the illustrated embodiment heat dissipation device 130 is a microchannel 190 having a base 131 and a cover plate 132. Cover plate 132 is over base 131. A connection 140 between cover plate 132 and substrate 110 is also illustrated. Coolant inlet and outlet tubes 150 introduce coolant into and remove coolant from microchannel 190, as known in the art and as briefly discussed above.

Visible in FIG. 2, in addition to the elements of microelectronic package 100 previously discussed, are solder bumps 210 that connect die 120 to substrate 110, solder bumps 220 that connect microelectronic package 100 to a printed circuit board or the like (not shown), channels 233 and fins 234 of microchannel 190, and thermal interface material 240 that carries heat from die 120 to microchannel 190. A capacitor 250 is located within cover plate 132, as will be discussed in more detail below.

It was mentioned above that an increase in the distance between a decoupling capacitor and a device requiring the decoupled signal (such as die 120) may lead to an increase in unwanted inductance. Conversely, placing the decoupling capacitor closer to the device reduces the inductance. With that in mind, it should be noted that a typical computer chip such as die 120 may be approximately 100 micrometers (μm) thick, while a typical substrate may have a width of approximately 20 millimeters. It may readily be seen that a capacitor-located within cover plate 132 is likely to be much closer to die 120—perhaps as much as ten times closer or more—than would a typical die side or land side capacitor.

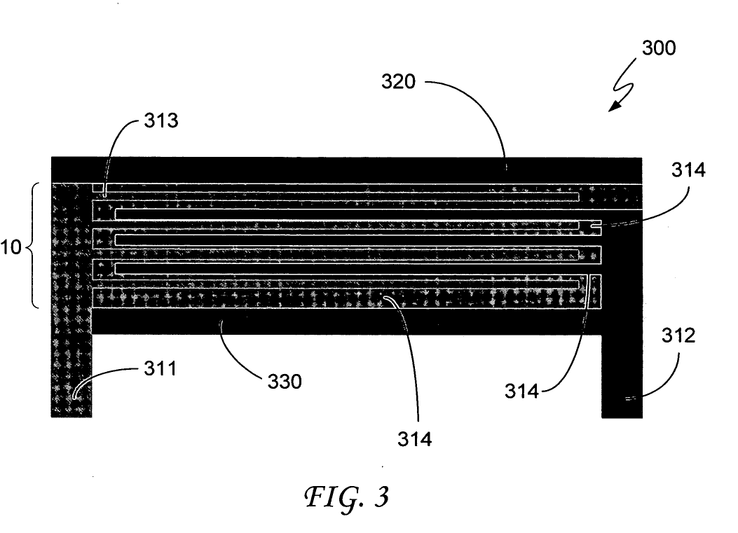

FIG. 3 is a cross sectional view of a microchannel cover plate 300 according to an embodiment of the invention. As illustrated in FIG. 3, microchannel cover plate 300 comprises a capacitor 310, which in turn comprises a terminal 311 and a terminal 312. (As an example, capacitor 310 can be similar to capacitor 250 of FIG. 2, and terminals 311 and 312 can be similar to connection 140, first shown in FIG. 1.) In one or more non-illustrated embodiments, capacitor 310 can comprise four, eight, twelve, sixteen, or some other number of terminals, as known in the art. As is also known in the art, increasing the number of terminals can increase the performance of the capacitor, at least in part because of inductance cancellation effects that become more efficient as the number of terminals is increased.

In one embodiment, terminal 311 of capacitor 310 is a power terminal in electrical contact with a power plane of a substrate, neither of which are shown in FIG. 3. In the same or another embodiment, terminal 312 of capacitor 310 is a ground terminal in electrical contact with a ground plane (not shown) of the substrate. Although the substrate and the aforementioned power plane and ground plane are not illustrated, such components are well known and a person of ordinary skill in the art will readily understand both their construction and the manner in which the relevant electrical connections between them may be made.

As an example, the substrate mentioned in the preceding paragraph may be similar to substrate 110, first shown in FIG. 1. Accordingly, microchannel cover plate 300 may form part of a microelectronic package that is similar to microelectronic package 100 of FIGS. 1 and 2. On a smaller scale, microchannel cover plate 300 may form part of a microchannel that is similar to microchannel 190, first shown in FIG. 1. In FIG. 3, however, several possible components of such a microelectronic package, including, for example, a die and a base of the microchannel, are not illustrated so as to avoid unnecessarily obscuring the depicted elements of microchannel cover plate 300.

Capacitor 310 further comprises an electrically conducting portion 313 that is electrically connected to terminal 311 and an electrically conducting portion 314 that is electrically connected to terminal 312. In the illustrated embodiment, electrically conducting portion 313 is made up of several layers or fingers, each of which are electrically connected to terminal 311. Similarly, electrically conducting portion 314 is also made up of several layers or fingers, each of which are electrically connected to terminal 312. In general, a capacitor with more such layers will perform better than a capacitor with fewer layers, but any attempt to increase the number of such layers should be undertaken with an understanding that at some point adding more layers may come into conflict with the somewhat opposing goal of maintaining a small form factor for microchannel cover plate 300 and for microelectronic package 100 (shown in FIGS. 1 and 2). Nevertheless, a typical microchannel cover plate has a thickness large enough that as many layers as desired are likely to be easily accommodated therein.

In the illustrated embodiment, the layers making up electrically conducting portion 313 alternate with those making up electrically conducting portion 314, and terminals 311 and 312 act as lags that match the pattern of the layers and form a connection along the sides of capacitor 310. In a non-illustrated embodiment, the layers making up electrically conducting portions 313 and 314 could be connected with a via or the like that is formed through the ends of all of the layers, such as at one side or the other of capacitor 310.

An electrically insulating portion or dielectric 315 separates electrically conducting portions 313 and 314 from each other. In one embodiment dielectric 315 comprises a material having a high dielectric constant and is thus what is frequently referred to as a high-k material, a high-k dielectric, or the like. Silicon dioxide has a dielectric constant (κ) of approximately 3.9. (Although the dielectric constant is often represented by the Greek letter κ, it is usually the lower case Roman letter “k” that is used in such phrases as “high-k material,” and such a convention will be followed here.) The dielectric constant of a vacuum, which is used as a scale reference point, is defined as 1. Accordingly, any material having a dielectric constant greater than about 5 or 10 would likely properly be considered a high-k material.

The capacitance C of capacitor 310 may be represented by the equation:

$$C = \frac{{κε}_{0} A}{t} \qquad ( Equation 1 )$$

where A represents the capacitor area, κ, as noted above, represents the dielectric constant, and ε₀ represents the permittivity of free space. As mentioned above, greater capacitances are capable of attenuating noise at higher frequencies, and high frequency noise in an increasingly vexing problem in today's high performance computer chips. Accordingly, one reason that a high-k material might be desirable in capacitor 310 is that its use increases the capacitance of capacitor 310 over what that capacitance would be if a dielectric with a lower dielectric constant were used, assuming constancy of the other variables.

As an example, the high-k dielectric material used in an embodiment of capacitor 310 may be a hafnium-based, a zirconium-based, or a titanium-based dielectric material that may have a dielectric constant of at least approximately 20. In a particular embodiment the high-k dielectric material is hafnium oxide having a dielectric constant of between approximately 20 and approximately 40. In a different particular embodiment the high-k dielectric material is zirconium oxide having a dielectric constant of between approximately 20 and approximately 40. In another particular embodiment the high-k dielectric material is barium titanate having a dielectric constant of between approximately 50 and approximately 200.

Equation 1, above, makes clear that an increase in capacitor area A results in an increase in capacitance C. For a typical discrete die side or land side capacitor used for decoupling purposes with a computer chip, the area A may be approximately 40 square millimeters. In contrast, a typical microchannel cover plate may have an area of approximately 100 square millimeters. The significantly larger area of the microchannel cover plate affords ample opportunity to increase area A for a capacitor according to an embodiment of the invention over the likely area of a typical die side or land side capacitor, and this, as mentioned, means larger capacitances are more easily obtainable when capacitors according to an embodiment of the invention are used.

Referring still to FIG. 3, microchannel cover plate 300 further comprises a surface 320 and a surface 330, both of which are formed from a non-electrically conducting material such as ceramic or the like. Surfaces 320 and 330 provide support and structure for microchannel cover plate 300.

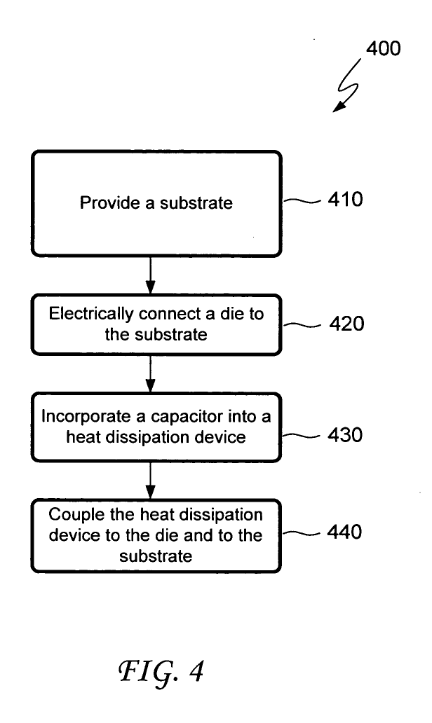

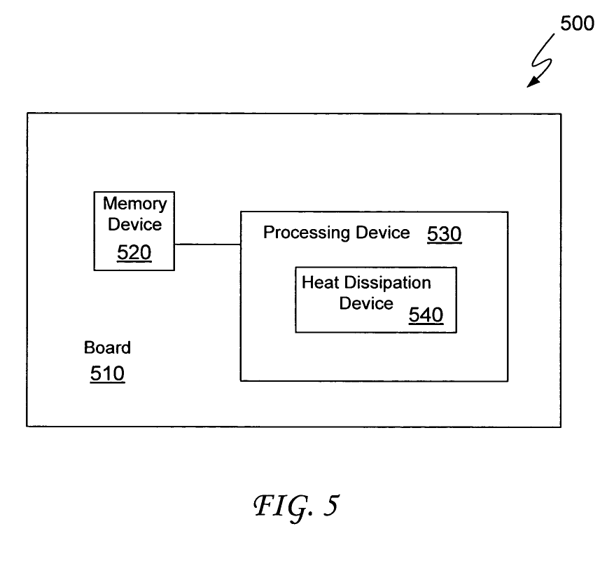

FIG. 4 is a flowchart illustrating a method 400 of manufacturing a microelectronic package according to an embodiment of the invention. A step 410 of method 400 is to provide a substrate. As an example, the substrate can be similar to substrate 110, first shown in FIG. 1. Accordingly, in one embodiment step 410 comprises providing a power plane and a ground plane.

A step 420 of method 400 is to electrically connect a die to the substrate. As an example, the die can be similar to die 120, first shown in FIG. 1. As another example, the electrical connection between the die and the substrate can be made using a solder material such as solder bumps 210, first shown in FIG. 2.

A step 430 of method 400 is to incorporate a capacitor into a heat dissipation device. As an example, the capacitor can be similar to capacitor 250, first shown in FIG. 2, and the heat dissipation device can be similar to heat dissipation device 130, first shown in FIG. 1. In one embodiment step 430 comprises forming a base of the heat dissipation device, forming a first surface of a cover plate of the heat dissipation device over the base, forming a plurality of alternating electrically conducting and electrically insulating layers over the first surface of the cover plate, and forming a second surface of the cover plate over the plurality of alternating electrically conducting and electrically insulating layers.

As an example, the base of the heat dissipation device can be similar to base 131, first shown in FIG. 1. As another example, the cover plate can be similar to cover plate 132, first shown in FIG. 1, and the first surface and the second surface of the cover plate can be similar to, respectively, surface 330 and surface 320 of microchannel cover plate 300, all of which are shown in FIG. 3. As still another example, the plurality of alternating electrically conducting layers can be similar to one or both of electrically conducting portions 313 and 314, both of which are shown in FIG. 3, and the plurality of electrically insulating layers can be similar to dielectric 315, also shown in FIG. 3, such that the plurality of electrically insulating layers can comprise, in one embodiment, a high-k dielectric material. As mentioned above, the plurality of alternating electrically conducting and electrically insulating layers and the dielectric layer form a capacitor within the cover plate of the heat dissipation device that may be similar to capacitor 250, shown in FIG. 2.

In one embodiment, forming a plurality of alternating electrically conducting and electrically insulating layers comprises depositing a metal layer such as copper, aluminum, gold, or the like over the first surface of the cover plate. As an example, the deposition can be accomplished using a plating process, a vapor deposition process such as physical vapor deposition (PVD), chemical vapor deposition (CVD), or the like, or some similar process. Following the deposition of the metal layer, a layer of dielectric material may be deposited. Optionally, a barrier layer may be formed between the metal and dielectric layers. The layers may then be electrically connected to a package containing the heat dissipation device according to techniques described herein or to other techniques as known in the art.

In the same or another embodiment, step 430 comprises forming a first terminal and a second terminal and electrically connecting the first terminal and the second terminal to the substrate. As an example, the first terminal and the second terminal can be similar to terminal 311 and to terminal 312, both of which are shown in FIG. 3. In one embodiment, step 430 comprises forming a power terminal of the capacitor and forming a ground terminal of the capacitor. More specifically, in one embodiment, forming the first terminal comprises forming a power terminal or a ground terminal and forming the second terminal also comprises forming a power terminal or a ground terminal such that the capacitor comprises both a power terminal and a ground terminal. As another example, electrically connecting the first terminal and the second terminal to the substrate comprises electrically connecting the power terminal to the power plane and electrically connecting the ground terminal to the ground plane.

A step 440 of method 400 is to couple the heat dissipation device to the die and to the substrate. As an example, step 440 may comprise coupling the heat dissipation device to the die using a thermal interface material such as thermal interface material 240, shown in FIG. 2. As another example, step 440 may comprise coupling the heat dissipation device to the die using the thermal interface material and coupling the die to the substrate, thus forming a connection between the heat dissipation device and the substrate. As an example, the connection between the die and the substrate may be made using a solder material such as solder bumps 210, shown in FIG. 2. The couplings and connections mentioned above may be electrical connections, thermal connections, or both, as appropriate.

Because the capacitor is integrated into the cover plate of a microchannel, its manufacture may be independent of the manufacture of the substrate and the die. Such independence means a capacitor according to an embodiment of the present invention can be integrated very easily into existing substrate and die manufacturing processes, unlike alternative capacitor techniques such as thin film capacitors, array capacitors, and embedded capacitors, all of which require non-negligible, or even substantial, modifications to existing manufacturing processes. Such independence further allows yield liability to be decreased. Furthermore, it is significantly less expensive to integrate a capacitor into a microchannel cover plate, as according to an embodiment of the invention, than it is to manufacture, for example, a thin film integrated capacitor in silicon or in a substrate. For that reason, the vast majority of existing capacitors are discrete rather than integrated capacitors.

FIG. 5 is a schematic view of a system 500 according to an embodiment of the invention. As illustrated in FIG. 5, system 500 comprises a board 510, a memory device 520 disposed on board 510, a processing device 530 disposed on board 510 and coupled to memory device 520, and a heat dissipation device 540 over processing device 530. Heat dissipation device 540 comprises a base and a cover plate over the base, and the cover plate comprises a capacitor. Accordingly, heat dissipation device 540 can be similar to heat dissipation device 130 and processing device 530 can be similar to die 120, both of which were first shown in FIG. 1. Furthermore, heat dissipation device 540 may be coupled to processing device 530 in a manner that is similar to the way in which die 120 and heat dissipation device 130 are coupled to each other.

Still further, processing device 530 may be contained within a package (not explicitly illustrated in FIG. 5) that comprises a substrate having a power plane and a ground plane. Accordingly, the substrate can be similar to substrate 110, first shown in FIG. 1. The package can be similar to microelectronic package 100, also first shown in FIG. 1. Heat dissipation device 540 can comprise a capacitor that is similar to capacitor 310, shown in FIG. 3. Accordingly, the capacitor can comprise a first terminal and a second terminal that can be similar to terminal 311 and terminal 312, also shown in FIG. 3. As an example, the first terminal of the capacitor can be a power terminal in electrical contact with the power plane, and the second terminal of the capacitor can be a ground terminal in electrical contact with the ground plane.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic package and related method and system discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A microelectronic package comprising:
a substrate;
a die electrically connected to the substrate; and
a heat dissipation device coupled to the die,
wherein:
the heat dissipation device comprises a capacitor.

2. The microelectronic package of claim 1 wherein:
the heat dissipation device is a microchannel.

3. The microelectronic package of claim 2 wherein:
the microchannel comprises:
a base; and
a cover plate over the base; and
the capacitor is located within the cover plate.

4. The microelectronic package of claim 2 wherein:
the capacitor comprises a first terminal and a second terminal.

5. The microelectronic package of claim 4 wherein:
the substrate contains a power plane and a ground plane;
the first terminal of the capacitor is a power terminal in electrical contact with the power plane; and
the second terminal of the capacitor is a ground terminal in electrical contact with the ground plane.

6. The microelectronic package of claim 4 wherein:
the capacitor comprises a high-k dielectric material.

7. The microelectronic package of claim 6 wherein:
the capacitor comprises a plurality of electrically conducting layers separated from each other by the high-k dielectric material.

8. The microelectronic package of claim 7 wherein:
a first portion of the electrically conducting layers are connected to the first terminal;
a second portion of the electrically conducting layers are connected to the second terminal; and
the first terminal is spaced apart from the second terminal.

9. The microelectronic package of claim 1 wherein:
the capacitor comprises at least four terminals.

10. A microelectronic package comprising:
a substrate;
a solder material over the substrate;
a die electrically coupled to the substrate via the solder material; and
a microchannel over the die and coupled to the die via a thermal interface material,
wherein:
the microchannel comprises:
a base; and
a cover plate over the base;
the cover plate comprises:
a first terminal;
a second terminal;
an electrically conducting material; and
an electrically insulating material; and
the first terminal, the second terminal, the electrically conducting material, and the electrically insulating material are arranged so as to form a capacitor.

11. The microelectronic package of claim 10 wherein:
the substrate contains a power plane and a ground plane;
the first terminal is a power terminal in electrical contact with the power plane; and
the second terminal is a ground terminal in electrical contact with the ground plane.

12. The microelectronic package of claim 11 wherein:
the electrically insulating material is a high-k material.

13. A method of manufacturing a microelectronic package, the method comprising:
providing a substrate;
electrically connecting a die to the substrate;
incorporating a capacitor into a heat dissipation device; and
coupling the heat dissipation device to the die and to the substrate.

14. The method of claim 13 wherein:
incorporating the capacitor into the heat dissipation device comprises:
forming a base of the heat dissipation device;
forming a first surface of a cover plate of the heat dissipation device over the base;
forming a plurality of alternating electrically conducting and electrically insulating layers over the first surface of the cover plate; and
forming a second surface of the cover plate over the plurality of alternating electrically conducting and electrically insulating layers,
wherein:
the plurality of alternating electrically conducting and electrically insulating layers form a capacitor within the cover plate of the heat dissipation device.

15. The method of claim 14 wherein:
forming the plurality of electrically insulating layers comprises forming a plurality of layers comprising a high-k dielectric material.

16. The method of claim 13 wherein:
incorporating the capacitor into the heat dissipation device further comprises:
forming a first terminal and a second terminal; and
electrically connecting the first terminal and the second terminal to the substrate.

17. The method of claim 16 wherein:
providing the substrate comprises providing a power plane and a ground plane;
forming the first terminal comprises forming a power terminal of the capacitor;
forming the second terminal comprises forming a ground terminal of the capacitor; and
electrically connecting the first terminal and the second terminal to the substrate comprises electrically connecting the power terminal to the power plane and electrically connecting the ground terminal to the ground plane.

18. A system comprising:
a board;
a memory device disposed on the board;
a processing device disposed on the board and coupled to the memory device;
a heat dissipation device over the processing device and comprising:
a base; and
a cover plate over the base,
wherein:
the cover plate comprises a capacitor.

19. The system of claim 18 wherein:
the processing device is contained within a package that comprises a substrate having a power plane and a ground plane;
the capacitor comprises a first terminal and a second terminal;
the first terminal of the capacitor is a power terminal in electrical contact with the power plane; and
the second terminal of the capacitor is a ground terminal in electrical contact with the ground plane.

20. The system of claim 19 wherein:
the capacitor comprises a high-k dielectric material.
